(19) United States
(12) Patent Application Publication
(10) Pub. No.: US 2021/0350039 A1
(43) Pub. Date: Nov. 11, 2021

(54) Graphical Representation for Datasets

(71) Applicant: Maron Electric Company, Skokie, IL (US)

(72) Inventors: Ross C. Reichert, Elmhurst, IL (US); Eric F. Nixon, Skokie, IL (US); Andrew J. Najem, Chicago, IL (US)

(21) Appl. No.: 16/867,731

(22) Filed: May 6, 2020

(51) Int. Cl. G06F 30/13; G06F 16/242; G06F 16/23; G06F 16/22; G06Q 10/08; G06F 3/0486

(52) U.S. Cl. CPC G06F 30/13; G06F 16/2428; G06F 3/0486; G06F 16/2282; G06Q 10/0833; G06F 16/2358

(57) ABSTRACT

The invention provides a method of automatically generating models for a dataset, comprising the steps of storing coordinates for a first dataset in a database, storing status reports as a second dataset in the database corresponding to the first dataset, exporting a graphical representation of the first dataset to render a graphical visualization of the relationship between the first dataset and a second dataset using data values, plotting of individual coordinates of the first dataset onto the graphical visualization using the data values, displaying the second dataset onto the graphical visualization to provide a graphical view of data from the status reports in a corresponding location to the first dataset, saving the graphical view to the memory and displaying the graphical view on a monitor.

The invention pertains to a computer system and a method of generating graphical representations for multiple dataset information including the plotting of dataset information.

### BACKGROUND

Many projects combine multiple datasets representing differing components, specialties, categories, genus or species. For example, in the construction trade the combination of many components go into the construction of a building. Datasets regarding the multiple components, when combined, are useful during the construction process to coordinate delivery and assembly of such components. While combination of such datasets was known, the present invention provides a novel mechanism and system for combining such datasets and displaying them graphically.

### SUMMARY

The present invention pertains to a method of automatically generating models for a dataset, comprising the steps of, at a computer system, having one or more processors and memory, storing coordinates for a first dataset in a database. The steps also include storing status reports as a second dataset in the database corresponding to the first dataset and exporting a graphical representation of the first dataset to render a graphical visualization of the relationship between the first dataset and a second dataset using data values. The steps also include plotting of individual coordinates of the first dataset onto the graphical visualization using the data values, displaying the second dataset onto the graphical visualization to provide a graphical view of data from the status reports in a corresponding location to the first dataset and saving the graphical view to the memory and displaying the graphical view on a monitor.

In an embodiment the first and second datasets pertain to architectural drawings and components of a building being constructed according to the architectural drawings. The method further comprises the steps of receiving the architectural drawings by the computer aided design department of a contractor responsible for managing a project according to the architectural drawings. The method further comprises the steps of storing in a table each of the coordinates from the first dataset, where the coordinates are mapped in accordance with size and scale of the architectural drawings.

In addition, the method comprises the steps of plotting the coordinates for the lighting fixtures according to the graphical view, wherein the graphical view includes a ceiling plan view taken from the architectural drawings. The method wherein the data properties of each dataset include a dataset format selected from the group consisting of categorical and quantitative and a dataset type selected from the group consisting of integer, real, Boolean and time. The method further comprising generating one or more statistical models in accordance with predefined heuristics for modeling a relationship between the first and second dataset, wherein the predefined heuristics include: selecting one of the two datasets from a user description as an independent variable and the other of the two datasets as a response variable of the one or more statistical models. The method wherein each of the one or more statistical models has a model type including linear, polynomial, exponential, logarithmic and transcendental.

The method further comprising the graphical view of the dataset corresponding to architectural drawings of the components covered in the first and second datasets.

The method wherein the second dataset pertains to shipping reports comprising data including date of delivery, light fixture, backorder status, damage reports and re-order status. The method wherein the first and second datasets pertain to electrical fixtures including lighting fixtures. The method wherein a user description is generated by a user dragging and dropping the first and second datasets into respective dataset containers of a graphical user interface.

The method comprising the steps of storing on a server the graphical view to be accessed by one of a contractor, subcontractor, tradesman, architect, developer and site attorney. The method wherein the subcontractor may control access to the database. The method wherein the second dataset is queried using the same installation space parameter. The method further comprising the steps of updating shipping status information by a lighting vendor, receiving the shipping status information by an electrical contractor and displaying the updated shipping status information to a report. The method further comprising the steps of storing the second dataset including shipping reports in the database, the graphical view stored in a server connected to the database and providing access to the server via a secure internet connection.

In an embodiment, the computer system, comprises memory; one or more processors; and at least one program stored in the memory, wherein the at least one program, when executed by the one or more processors, causes the computer system to, receive a graphical view of a first dataset, wherein the graphical view specifies a relationship between the first dataset and a second dataset; and render at least one graphical representation of the second dataset model on top of the graphical visualization of the relationship between the first and second dataset and the first dataset pertaining to components of a building being constructed and the second dataset pertaining to status of the components of the building being constructed. The computer system wherein the first and second dataset pertain to lighting fixtures and the second dataset pertaining to shipping status of lighting fixtures. The computer system further comprising instructions for comparing the data properties of the first and second datasets to determine a graphical view. The computer system further comprising displaying the second dataset onto the graphical visualization to provide a graphical view of data from the status reports in a corresponding location to the first dataset saving the graphical view to the memory and displaying the graphical view on a monitor.

The computer system wherein the graphical view includes an overlay area for providing the graphical visualization and a key area for defining the parameters in the overlay area. The computer system wherein the parameters are represented by one of color, shape or description. The computer system wherein the key area includes a chart depicting one of item number, item description, item count, finish-by date and needed-by date. The computer system further comprising a monitor including one of a smart phone screen, a screen of a laptop and a monitor connected to a desktop computer.

In another embodiment, the invention provides a non-transitory computer readable storage medium storing a computer program product that includes one or more programs configured for execution by a computer system that includes one or more processors and memory, the one or more programs comprising instructions that, if executed by the computer system, cause the computer system to: receive a user description of a graphical view of a first dataset, wherein the user description specifies a relationship between the first dataset and a second dataset, render a graphical visualization of the relationship between the first and second dataset using data values associated with the first and second dataset, receive a user instruction to render the graphical visualization of the relationship between the first and second datasets using data values associated with the first and second datasets, in response to the user instruction, determine a set of data properties for each of the first and second datasets, the first dataset pertaining to the location of lighting fixtures identified in architectural drawings and the second dataset pertaining to status of lighting fixtures identified in the architectural drawings; generate one or more visual models of the datasets in accordance with the data values associated with the first and second datasets; and render at least one graphical representation of the one or more datasets.

### BRIEF DESCRIPTION OF DRAWINGS

FIG. 1 is a schematic view of the database inputs and outputs of the present invention;

FIG. 2 is a flow chart of the steps of the present invention;

FIG. 3 is a graph showing points plotted on a graph taken from area F3 from FIG. 4a;

FIG. 4a is graphical representation of fixtures combining multiple datasets including highlighted area F3;

FIG. 4b is a chart displaying types of fixtures for a dataset; and

FIG. 4c is a chart denoting characteristics of fixture types for a dataset.

Like reference numbers and designations from the drawing figures indicate like elements. The drawing figures represent only preferred embodiments which are described in the following Detailed Description. The invention is not limited to solely the preferred embodiments described.

### DETAILED DESCRIPTION

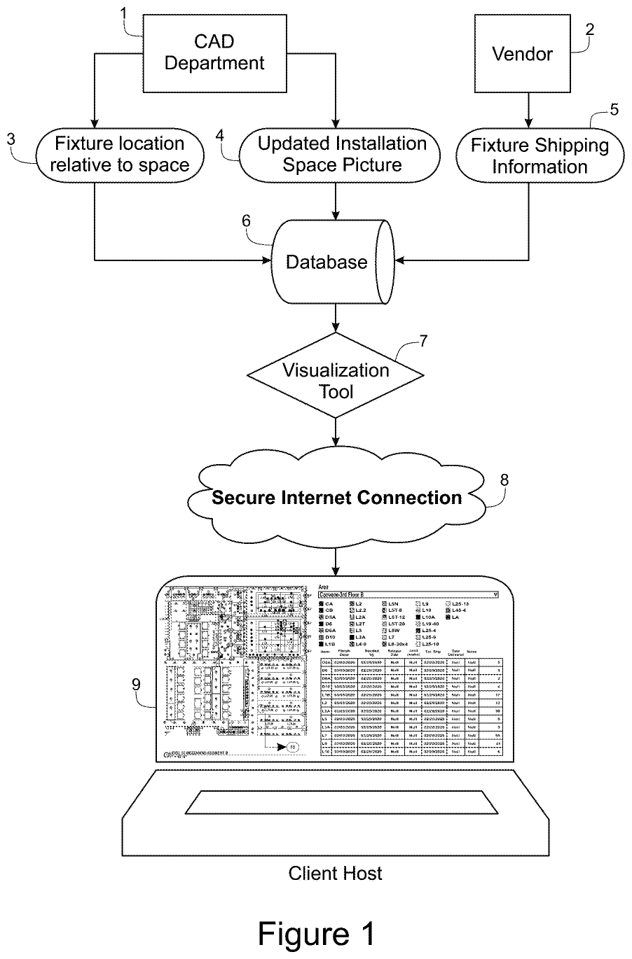

An embodiment of the present invention is described with respect to FIGS. 1-4c. In this embodiment, a first dataset is composed of architectural drawings of floorplan (ceiling) of a building under construction and a second dataset composed of lighting fixture characteristics or status. However, it is to be understood that the datasets could be for components other than for construction or fixtures and the presently described embodiment is but an example of the present invention.

An embodiment of the invention is described with respect to FIG. 1. A CAD (computer aided draft/design) department 1 receives drawings for bidding and construction, organizes the drawings and develops drawings and/or datasets (collectively, “datasets”) pertaining to a construction project. Separately a vendor 2, such as a lighting fixture distributor provides dataset information such as fixture shipping status reports/information. Such datasets may also include lighting fixture location relative to the space 3 or an updated installation space picture or drawing 4, in addition to fixture shipping information 5. Such dataset info 3, 4 is uploaded to database 6. Coordinates for each fixture 3 in each area of the construction space are recorded and stored. Fixture shipping reports 5 are stored in the subcontractor's fixture shipping report database to hold information specified for the subcontractors lighting fixture report. Individual fixture coordinates are plotted by the visualization tool 7 onto the selected fixture installation space and onto the exported picture from the installation space for the light fixtures. A secure internet connection 8 is used to transmit the datasets and output from the visualization tool 7 to a preselected client host computer 9.

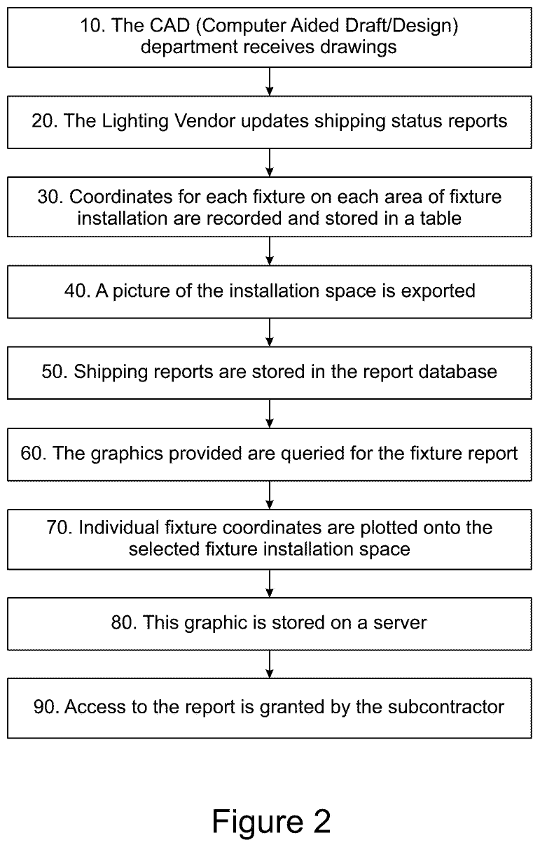

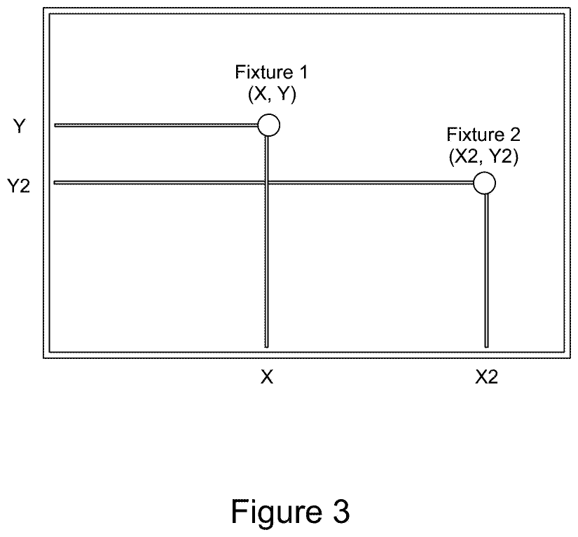

Following is a description of the steps of FIG. 2. A CAD department 10 receives drawings for bidding and construction. The CAD department then organizes the drawings and develops drawings and/or datasets pertaining to a construction project. Such datasets may include lighting fixture location relative to the space 30 or an updated installation space picture or drawing 40. Such dataset info 30, 40 is uploaded to database 60. Coordinates for each fixture 30 in each area of the construction space are recorded and stored in a graph (FIG. 3) by updating drawings provided by the CAD department. The fixture coordinates are recorded according to the size of the drawing and scale (See FIG. 3).

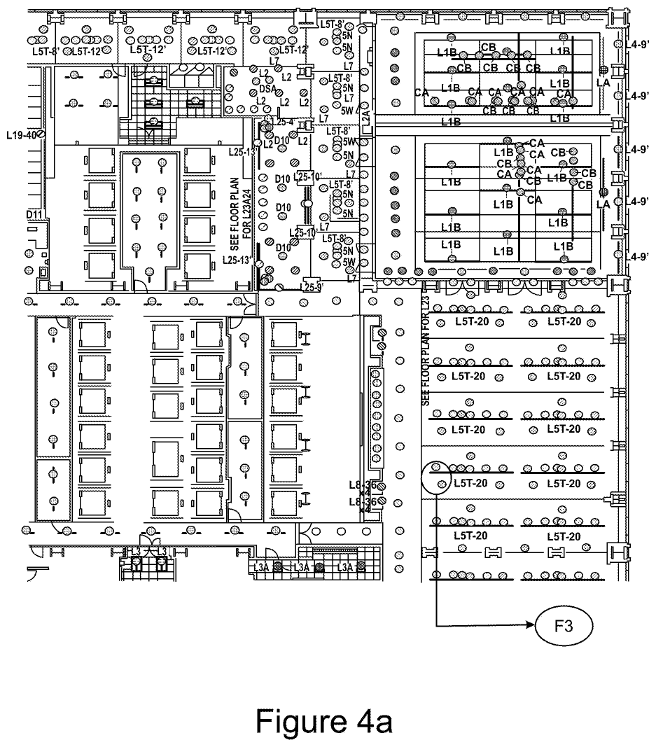

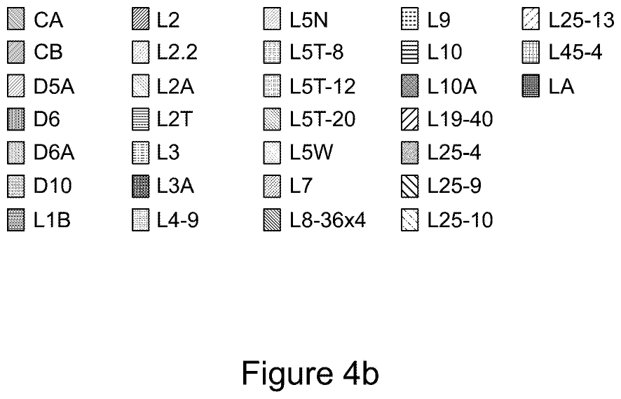

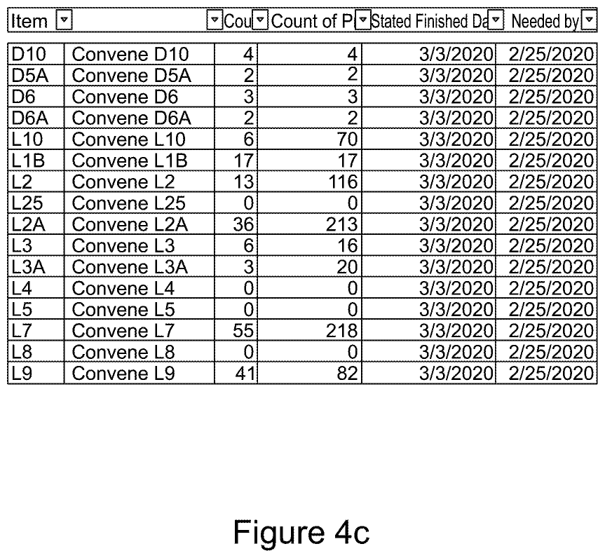

Separately a vendor 20, such as a lighting fixture distributor, provides dataset information such as fixture shipping status reports/information 50. The shipping information may include shipping status reports and data relevant to fixtures on each project and forwards the data to the electrical contractor. A drawing/picture of the installation space is exported from an original drawing, such as a ceiling plan of the architectural drawings. The picture is stored in the database 60 and used as the first layer of the picture map (FIG. 4a) that is used for plotting the coordinates of the light fixtures.

The fixture vendor 20 updates shipping data to be displayed in a report including time and date of delivery or packing information. Such dataset information is uploaded to database 60 to be queried for a fixture report. Fixture shipping reports 50 are stored in the subcontractor's fixture shipping report database to hold information specified for the subcontractors lighting fixture report. An example of a datasource is Microsoft SQL Server 2016 or Microsoft Access.

From the database 60, the dataset information is transmitted to visualization tool 70 where the multiple datasets are combined into a single graphical representation. An example, of software for the visualization tool is Tableau Server or Microsoft Power BI. Using a secure internet connection 80 the graphical representation is available in the cloud for display in a client host computer 90 (laptop). Access is available through a secure internet connection and login information for the reports may be administered locally with the database 60 to avoid unauthorized external access. Access to the report may be granted by a subcontractor (e.g. through a domain login) via a host computer 90 to clients through a web interface. Individual fixture coordinates are plotted by the visualization tool 70 onto the selected fixture installation space and onto the exported picture from the installation space for the light fixtures. The shipping and general fixture data is queried by the selected installation space and is displayed on the graphic representation of the visualization tool 70. Using the same parameters, the image of the installation space is queried and the coordinates are plotted with respect to the size of the image. Such an image is recorded when exported from the print of the installation space.

Table 1 depicting fixture location dataset information, such as x, y coordinates of light fixture installation locations is provided below:

TABLE 1

| Space | Fixture | X Coordinate | Y Coordinate |
|---|---|---|---|
| Floor/Area A | Fixture 1 | X | Y |
| Floor/Area A | Fixture 2 | X2 | Y2 |

FIG. 3 depicts a graph of the floor area of building under construction showing the x, y coordinates in the first instance and for a second fixture x2 and y2 coordinates taken from Table 1. FIG. 3 depicts the rendering of two fixtures taken from area F3 of FIG. 4a, but it is understood that using a chart such as shown in Table 1 (infra), many more fixture locations may be rendered on a graph showing hundreds or thousands of fixture locations, such as depicted in FIG. 4a.

FIG. 4a is a composite of at least three datasets. The first dataset being fixture location (such as from Table 1). The second dataset is FIG. 4b depicting a graphical representation/chart of types of fixtures. The third dataset is shown in FIG. 4c that is a dataset in the configuration of chart that denotes characteristics of fixtures. For example, “D10” denotes a Convene (project) D10 light fixture, as shown in FIG. 4c. (Color coding may be used to denote the fixture type.) Also for example, “D5A” denotes Convene and model D5A as shown in FIG. 4c. The combination of the dataset information is integrated using a visualization tool 70 to prepare a graphical representation, such as shown by FIG. 4a.

A method of automatically generating models (FIG. 4a) for a dataset (Table 1), includes having one or more processors and memory, storing coordinates for a first dataset in a database 60. Status reports 50 as a second dataset are stored in the database 60. The status reports 50 corresponding to the first dataset of fixture location coordinates 30 are exported using a visualization tool 70 generating a graphical representation (FIG. 4b) of the first dataset to render a graphical visualization of the relationship between the first dataset and a second dataset (FIG. 4a) using data values (Table 1). Plotting of individual coordinates (Table 1) of the first dataset occurs onto the graphical visualization using the data values 30, 40, 50 and displaying the second dataset onto the graphical visualization to provide a graphical view (FIG. 4a) of data from the status reports in a corresponding location to the first dataset. The graphical view (FIG. 4a) is saved to the memory and displayed on a monitor 90.

The first and second datasets pertain to architectural drawings 40 and components of a building 30 being constructed according to the architectural drawings. The architectural drawings 40 are received by the computer aided design department 10 of a contractor responsible for managing a project according to the architectural drawings 40. Coordinates x, x2, y, y2 (FIG. 3) are mapped in accordance with size and scale of the architectural drawings 40.

Plotting the coordinates x, x2, y, y2 for the lighting fixtures F3 (FIG. 4a) are accomplished according to the graphical view 40, where the graphical view includes a ceiling plan view taken from the architectural drawings 40. The data properties of each dataset 30, 40, 50 include a dataset format including categorical, quantitative, integer, real, Boolean and time. Generating statistical models with predefined heuristics for modeling a relationship between the first and second dataset 30, 40, from a user description as an independent variable and the other of the two datasets as a response variable of the one or more statistical models including linear, polynomial, exponential, logarithmic and transcendental. The second dataset pertains to shipping reports 50 including date of delivery, light fixture, backorder status, damage reports and re-order status (FIG. 4c). The description may be generated by a user dragging and dropping the first and second datasets 30, 40 into respective dataset containers of a graphical user interface.

A server 80 may be used for the graphical view to be accessed by one of a contractor, subcontractor, tradesman, architect, developer and site attorney. The subcontractor may control access to the database 60. The same installation space parameter may be used for either dataset. Updating shipping status information may be done by a lighting vendor 20, receiving the shipping status information by an electrical contractor 50 and displaying the updated shipping status information. Access is provided to the server 80 via a secure internet connection. An example of authentication software is Microsoft Active Directory.

Various examples of the present invention have been described. These and other embodiments would be known to those of ordinary skill in the art and are within the scope of the following claims.

What is claimed is:

1. A method of automatically generating models for a dataset, comprising the steps of: at a computer system having one or more processors and memory,
storing coordinates for a first dataset in a database;
storing status reports as a second dataset in the database corresponding to the first dataset;
exporting a graphical representation of the first dataset to render a graphical visualization of the relationship between the first dataset and a second dataset using data values;
plotting of individual coordinates of the first dataset onto the graphical visualization using the data values;
displaying the second dataset onto the graphical visualization to provide a graphical view of data from the status reports in a corresponding location to the first dataset;
saving the graphical view to the memory; and
displaying the graphical view on a monitor.

2. The method of claim 1, wherein the first and second datasets pertain to architectural drawings and components of a building being constructed according to the architectural drawings.

3. The method of claim 2, further comprising the steps of: receiving the architectural drawings by the computer aided design department of a contractor responsible for managing a project according to the architectural drawings.

4. The method of claim 2, further comprising the steps of: storing in a table each of the coordinates from the first dataset, where the coordinates are mapped in accordance with size and scale of the architectural drawings.

5. The method of claim 2, further comprising the steps of: plotting the coordinates for the lighting fixtures according to the graphical view, wherein the graphical view includes a ceiling plan view taken from the architectural drawings.

6. The method of claim 1, wherein the data properties of each dataset include a dataset format selected from the group consisting of categorical and quantitative and a dataset type selected from the group consisting of integer, real, Boolean and time.

7. The method of claim 1, further comprising generating one or more statistical models in accordance with predefined heuristics for modeling a relationship between the first and second dataset, wherein the predefined heuristics include: selecting one of the two datasets from a user description as an independent variable and the other of the two datasets as a response variable of the one or more statistical models.

8. The method of claim 7, wherein each of the one or more statistical models has a model type including linear, polynomial, exponential, logarithmic and transcendental.

9. The method of claim 1, further comprising the graphical view of the dataset corresponding to architectural drawings of the components covered in the first and second datasets.

10. The method of claim 1, wherein the second dataset pertains to shipping reports comprising data including date of delivery, light fixture, backorder status, damage reports and re-order status.

11. The method of claim 1, wherein the first and second datasets pertain to electrical fixtures including lighting fixtures.

12. The method of claim 1, wherein a user description is generated by a user dragging and dropping the first and second datasets into respective dataset containers of a graphical user interface.

13. The method of claim 1, further comprising the steps of storing on a server the graphical view to be accessed by one of a contractor, subcontractor, tradesman, architect, developer and site attorney.

14. The method of claim 13, wherein the subcontractor may control access to the database.

15. The method of claim 1, wherein the second dataset is queried using the same installation space parameter.

16. The method of claim 1, further comprising the steps of: updating shipping status information by a lighting vendor, receiving the shipping status information by an electrical contractor and displaying the updated shipping status information to a report.

17. The method of claim 1, further comprising the steps of: storing the second dataset including shipping reports in the database, the graphical view stored in a server connected to the database and providing access to the server via a secure internet connection.

18. A computer system, comprising: memory; one or more processors; and at least one program stored in the memory, wherein the at least one program, when executed by the one or more processors, causes the computer system to, receive a graphical view of a first dataset, wherein the graphical view specifies a relationship between the first dataset and a second dataset; and render at least one graphical representation of the second dataset model on top of the graphical visualization of the relationship between the first and second dataset; and the first dataset pertaining to components of a building being constructed and the second dataset pertaining to status of the components of the building being constructed.

19. The computer system of claim 18, wherein the first and second dataset pertain to lighting fixtures and the second dataset pertaining to shipping status of lighting fixtures.

20. The computer system of claim 18, further comprising instructions for comparing the data properties of the first and second datasets to determine a graphical view.

21. The computer system of claim 18, further comprising: displaying the second dataset onto the graphical visualization to provide a graphical view of data from the status reports in a corresponding location to the first dataset;
saving the graphical view to the memory; and
displaying the graphical view on a monitor.

22. The computer system of claim 21 wherein the graphical view includes an overlay area for providing the graphical visualization and a key area for defining the parameters in the overlay area.

23. The computer system of claim 22 wherein the parameters are represented by one of color, shape or description.

24. The computer system of claim 22 wherein the key area includes a chart depicting one of item number, item description, item count, finish-by date and needed-by date.

25. The computer system of claim 18, further comprising a monitor including one of a smart phone screen, a screen of a laptop and a monitor connected to a desktop computer.

26. A non-transitory computer readable storage medium storing a computer program product that includes one or more programs configured for execution by a computer system that includes one or more processors and memory, the one or more programs comprising instructions that, if executed by the computer system, cause the computer system to: receive a user description of a graphical view of a first dataset, wherein the user description specifies a relationship between the first dataset and a second dataset; render a graphical visualization of the relationship between the first and second dataset using data values associated with the first and second dataset; receive a user instruction to render the graphical visualization of the relationship between the first and second datasets using data values associated with the first and second datasets; in response to the user instruction, determine a set of data properties for each of the first and second datasets, the first dataset pertaining to the location of lighting fixtures identified in architectural drawings and the second dataset pertaining to status of lighting fixtures identified in the architectural drawings; generate one or more visual models of the datasets in accordance with the data values associated with the first and second datasets; and render at least one graphical representation of the one or more datasets.
